(19) United States
(12) Patent Application Publication
(10) Pub. No.: US 2025/0125306 A1
(43) Pub. Date: Apr. 17, 2025

(54) PACKAGING METHOD AND PACKAGING BODY

(71) Applicant: SKY CHIP INTERCONNECTION TECHNOLOGY CO., LTD., SHENZHEN (CN)

(72) Inventors: Shijie ZHONG, SHENZHEN (CN); Guanqiang SONG, SHENZHEN (CN); Yuhong LI, SHENZHEN (CN); Yun LEI, SHENZHEN (CN)

(73) Assignee: SKY CHIP INTERCONNECTION TECHNOLOGY CO., LTD., SHENZHEN (CN)

(21) Appl. No.: 18/981,551

(22) Filed: Dec. 15, 2024

Related U.S. Application Data
(63) Continuation of application No. PCT/CN2024/111143, filed on Aug. 9, 2024.

(30) Foreign Application Priority Data
Oct. 12, 2023 (CN) 202311324523.7

(51) Int. Cl. H01L 23/00; C03C 15/00; C23F 1/16; C23F 1/32; C25D 5/02; C25D 7/00; H01L 21/56; H01L 23/29

(52) U.S. Cl. CPC H01L 24/96; C03C 15/00; C23F 1/16; C23F 1/32; C25D 5/022; C25D 7/00; H01L 21/561; H01L 24/19; H01L 24/20; H01L 23/293; H01L 2224/19; H01L 2224/215; H01L 2224/95001

(57) ABSTRACT

A packaging method and a packaging body are provided. The packaging method includes: obtaining a mounting plate defining multiple mounting holes; disposing a target device in each of the multiple mounting holes; performing plastic sealing on the multiple mounting holes to form packaging bodies, and each of the packaging bodies wrapping the target device; and performing chemical etching on the mounting plate until each of the packaging bodies is separated from each other, and obtaining multiple independent packaging bodies. In this way, appearance quality is ensured, separation efficiency of the large plate is improved, freedom of batch separation of the packaging bodies is improved, and more possibilities for the shape of each of the packaging bodies are provided.

### CROSS REFERENCE TO RELATED APPLICATIONS

The present disclosure is a continuation of International Patent Application No. PCT/CN2024/111143, filed Aug. 9, 2024, which claims foreign priority to Chinese Patent Application No. 202311324523.7, filed Oct. 12, 2023, both of which are hereby incorporated by reference in their entireties.

### TECHNICAL FIELD

The present disclosure relates to the technical field of device packaging, and in particular to a packaging method and a packaging body.

### BACKGROUND

Packaging refers to manufacturing a shell used for a target device, and the packaging plays a role in mounting, fixing, sealing and protecting the devices, and enhancing electrical heating performance, etc.

In a later stage of manufacturing a packaging body, a large plate is required to be separated and cut to obtain multiple independent packaging bodies, so as to achieve batch manufacture. A traditional separation method includes cutter wheel cutting or laser cutting.

However, the cutter wheel cutting only is used in cutting along a straight line, and the more cutting paths, the slower the cutting speed. The efficiency of the laser cutting is very slow, and phenomena of thermal melting and blackening is occurred on the cutting paths.

### SUMMARY

A packaging method is provided and includes: obtaining a mounting plate defining multiple mounting holes; disposing a target device in a corresponding mounting hole of the multiple mounting holes; performing plastic sealing on the multiple mounting holes to form packaging bodies, and each of the packaging bodies wrapping the target device; and performing chemical etching on the mounting plate until each of the packaging bodies is separated from each other, and obtaining multiple independent packaging bodies.

A packaging method is provided and includes: performing chemical etching on an initial plate to obtain a mounting plate with a plurality of mounting holes; disposing a target device in each of the plurality of mounting holes to form a plurality of packaging bodies; and performing chemical etching on the mounting plate to separate the packaging bodies; The chemical etching includes chemically etching through hydrofluoric acid etching solution or chemically etching through metal etching solution.

A packaging body is provided, and the packaging body is manufactured by any one of the above packaging methods. The packaging body includes a plastic sealing layer and a target device, and the target device is received in the plastic sealing layer.

### BRIEF DESCRIPTION OF THE DRAWINGS

FIG. 1 is a flowchart of an embodiment of a packaging method in the present disclosure.

FIG. 2 is a flowchart of another embodiment of a packaging method in the present disclosure.

FIG. 3 is a structural schematic diagram of a first half manufacture process in the embodiment of FIG. 2.

FIG. 4 is a structural schematic diagram of a second half manufacture process in the embodiment of FIG. 2.

FIG. 5 is a structural schematic diagram of an embodiment of a mounting plate on which chemical etching is not performed in the embodiment of FIG. 2.

FIG. 6 is a structural schematic diagram of another embodiment of a mounting plate on which chemical etching is not performed in the embodiment of FIG. 2.

FIG. 7 is a structural schematic diagram of a packaging body according to an embodiment of the present disclosure.

### DETAILED DESCRIPTIONS

The technical solutions in embodiments of the present disclosure are clearly and completely described in conjunction with the drawings in the embodiments of the present disclosure. It is obvious that the described embodiments are only some embodiments of the present disclosure, and not all embodiments. All other embodiments acquired by those skilled in the art based on the embodiments in the present disclosure without the creative work are all within the scope of the present disclosure.

It should be noted that when directional indications (such as above, lower, left, right, front, rear . . . ) used in embodiments of the present disclosure are only used to explain relative position relationship, motion situation, etc. between components in a specific posture (as shown in the drawings). When the specific posture changes, the directional indication also changes accordingly.

In addition, the terms “first” and “second” in embodiments of the present disclosure are only used for description purposes and cannot be understood as indicating or implying relative importance or implicitly indicating the number of technical features indicated. Thus, features defined as “first” and “second” may explicitly or implicitly include at least one of the features. Moreover, the technical solutions of various embodiments may be combined with each other, but the technical solutions may be implemented by those skilled in the art. When the combination of technical solutions is contradictory or impossible to implement, it should be considered that this combination of technical solutions does not exist and is not within the scope of the present disclosure.

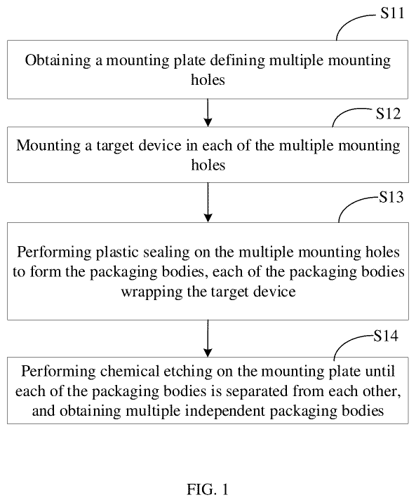

As shown in FIG. 1, FIG. 1 is a flowchart of an embodiment of a packaging method in the present disclosure.

An operation S11 includes: obtaining a mounting plate defining multiple mounting holes.

The mounting plate with multiple mounting holes is obtained. The mounting plate is required to be removed when the final packaging body is formed. Therefore, the mounting plate in this embodiment may be made of removable materials to cooperate with subsequent chemical etching operation for removal.

The multiple mounting holes are defined on the mounting plate, and the number of the mounting holes are set based on the requirements of batch manufacture of the packaging bodies. The number of the mounting holes may be 10, 20, 50, 100, 300, 500, 800, 1000, 3000, or 5000, etc., which may be set based on the actual situation.

In some embodiments, the multiple mounting holes on the mounting plate may be defined in an array to facilitate the manufacture of the packaging bodies. In another embodiments, the positions of the multiple mounting holes on the mounting plate may be determined based on the characteristics of a processing device, such that the processing device may manufacture multiple packaging bodies on the mounting plate.

An operation S12 includes: mounting a target device in each of the multiple mounting holes.

The target device may include but is not limited to one or more components including a chip, a resistor, a capacitor, a diode, a transistor, and an inductor, etc.

In some embodiments, the mounting holes may be mounting through-holes. The mounting of the target device may be achieved by placing a temporary support layer on one side of the mounting plate and then mounting the target device in the corresponding mounting through-holes from another side of the mounting plate opposite to the one side of the mounting plate until the target device attach to the temporary support layer, so as to complete the mounting of the target device. After fixing the target device through plastic sealing, the temporary support layer may be removed. The temporary support layer may include but is not limited to a temporary bonding adhesive, a tape, a glass substrate, a wooden substrate, or a metal substrate.

In some embodiments, the mounting holes may be mounting blind-holes that the bottom of the mounting blind-holes are not hollowed out, such that the target device may be directly mounted at the bottom of the corresponding mounting blind-holes.

An operation S13 includes: performing plastic sealing on the multiple mounting holes to form the packaging bodies, each of the packaging bodies wrapping the target device.

The plastic sealing material may include but is not limited to one or more types of insulation materials including epoxy resin, polyester resin (PET), polyimide, polyimide, polycarbonate (PC), bismaleimide triazine (BT), and ceramic based materials, etc.

In some embodiments, when the mounting holes are the mounting through-holes, plastic sealing is performed on the side of the mounting holes away from the temporary support layer, such that the plastic sealing material fills the mounting holes and fixes the target device.

In some embodiments, when the mounting holes are mounting blind-holes, plastic sealing is performed on the side of the mounting blind-holes away from the bottom of the mounting blind-holes, such that the plastic sealing material fills the mounting holes and fixes the target device.

After plastic sealing is performed, a relevant process manufacture may be performed based on electrical requirements of the packaging bodies to form the packaging bodies wrapping the target device. The process manufacture depends on the actual manufacture requirements of the packaging bodies and is not limited here. When there are no other electrical requirements for the packaging bodies, the plastic sealed structure may be directly used as the packaging bodies.

An operation S14 includes: performing chemical etching on the mounting plate until each of the packaging bodies is separated from each other, and obtaining multiple independent packaging bodies.

After manufacturing the multiple packaging bodies on the mounting plate, the mounting plate is removed by chemical etching to separate each of the packaging bodies and obtain multiple independent packaging bodies.

In some embodiments, the mounting plate is made of glass, and the chemical etching includes using hydrofluoric acid etching solution for chemical etching. In some embodiments, the mounting plate is made of metal, and chemical etching includes using metal etching solution for chemical etching. The metal etching solution may include acidic etching solution or hydrogen peroxide etching solution.

In other embodiments, the mounting plate may be made of other materials, as long as the etching solution used for chemical etching is capable of etching away the corresponding materials of the mounting plate.

In the above operations of this embodiment, the packaging method includes obtaining a mounting plate defining multiple mounting holes; disposing a target device in each of the multiple mounting holes; performing plastic sealing on the multiple mounting holes to form packaging bodies, each of the packaging bodies wrapping the target device; and performing chemical etching on the mounting plate until each of the packaging bodies is separated from each other, and obtaining multiple independent packaging bodies. In this way, the large plate is separated by chemical etching to obtain multiple independent packaging bodies. The separation path is not limited to a straight line, and the separation surface is not limited to a plane surface, which may greatly improve the freedom of batch separation of packaging bodies and provide more possibilities for the shape of each of the packaging bodies. The chemical etching does not cause phenomena such as thermal melting and blackening that affect the quality of the packaging bodies, thereby ensuring the appearance quality of the packaging bodies. In addition, etching and separation are simultaneously performed on all separation paths, without queuing in sequence, thereby greatly improving the separation efficiency of the large plate.

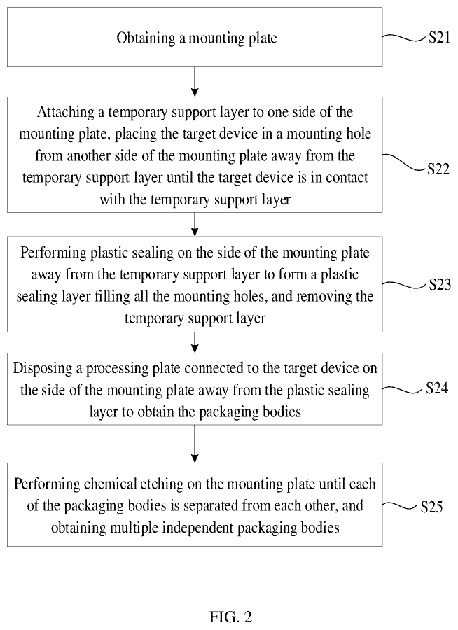

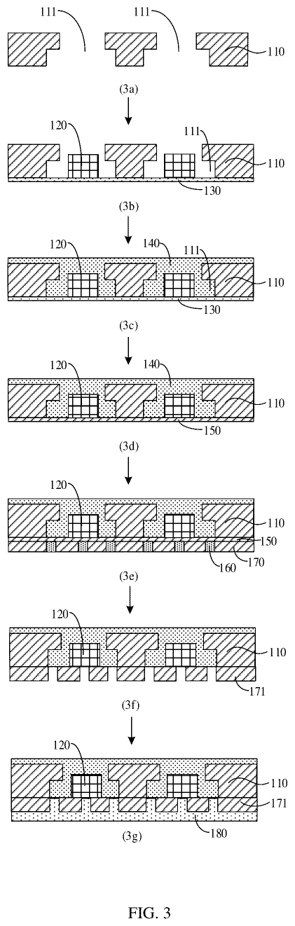

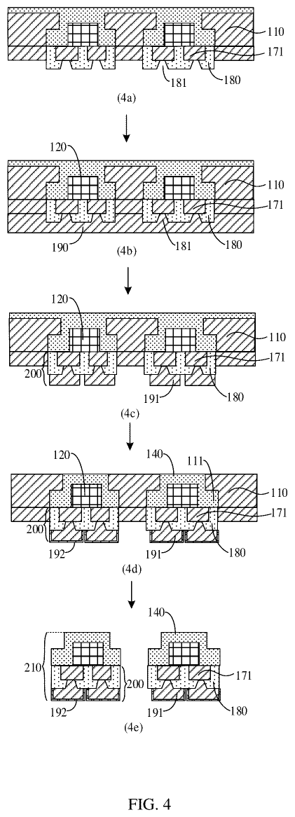

As shown in FIGS. 2-4, FIG. 2 is a flowchart of another embodiment of a packaging method in the present disclosure, FIG. 3 is a structural schematic diagram of a first half manufacture process in the embodiment of FIG. 2, and FIG. 4 is a structural schematic diagram of a second half manufacture process in the embodiment of FIG. 2.

An operation S21 includes: obtaining a mounting plate.

The method of obtaining the mounting plate may include: obtaining an initial plate. The initial plate is an entire piece of plate. The mounting plate is obtained by defining multiple mounting holes on the entire plate. Since the target device is required to be mounted inside the mounting plate, the thickness of the initial plate may be greater than or equal to the thickness of the target device for ease of accommodation.

In some embodiments, the method of defining the mounting holes may include: attaching a protective film to one entire side of the initial plate, exposing and developing the protective film based on an appearance size of each of packaging bodies to expose an area corresponding to each of the packaging bodies on the initial plate, performing chemical etching on the initial plate to form the multiple mounting holes, and removing the protective film. Since the target device is mounted in the corresponding mounting holes to form the packaging bodies through plastic sealing, the shape of each of the mounting holes is related to the appearance size of the corresponding packaging body. Each of the mounting holes is manufactured by chemical etching, and the freedom of chemical etching is used to improve the freedom of the appearance size of each of the mounting holes, thereby meeting the appearance size requirements of different packaging bodies.

In some embodiments, the method of defining the mounting holes may include: defining the multiple mounting holes on the initial plate through mechanical punching or laser ablation.

The mounting holes in this embodiment include but are not limited to mounting through-holes, mounting blind-holes, mounting threaded-holes, mounting step-holes, or mounting inclined-holes. In this embodiment, the mounting through-holes refer to through-holes with smooth and perpendicular hole walls, the mounting blind-holes refer to blind-holes with smooth and perpendicular hole walls, the mounting threaded-holes refer to through-holes or blind-holes with threaded-hole walls, the mounting step-holes refer to through-holes or blind-holes with step-hole walls, and the mounting inclined-holes refer to through-holes or blind-holes with inclined walls.

Different mounting holes in this embodiment may be configured to manufacture packaging bodies with different appearance shapes, thereby providing more possibilities for the shapes of the packaging bodies.

As shown in 3a of FIG. 3, the mounting holes being through-holes with step-hole walls is taken as an example for explanation in this embodiment.

A mounting plate 110 in this embodiment defines multiple mounting holes 111, and the mounting holes 111 are mounting step-holes.

The mounting step-holes in this embodiment may be formed through chemical etching on both opposite sides of the mounting plate 110 to obtain the mounting holes 111 with a step surface on the hole walls. In some embodiments, the mounting step-holes may be formed through mechanical punching on both opposite sides of the mounting plate 110 to obtain the mounting holes 111 with a step surface on the hole walls.

An operation S22 includes: attaching a temporary support layer to one side of the mounting plate, placing the target device in a mounting hole from another side of the mounting plate away from the temporary support layer until the target device is in contact with the temporary support layer.

When the mounting holes are through-holes, there may be no support for the mounting of the target device, therefore, the temporary support layer is required to be configured to support.

As shown in 3b of FIG. 3, a temporary support layer 130 is attached to one side of the mounting plate 110, the target device 120 is placed in a mounting hole 111 from the side of the mounting plate 110 away from the temporary support layer 130 until the target device 120 is in contact with the temporary support layer 130, such that the temporary support layer 130 may be configured to support the multiple target device 120.

The temporary support layer 130 may include but is not limited to a temporary bonding adhesive, a tape, a glass substrate, a wooden substrate, or a metal substrate. In some embodiments, the temporary support layer 130 may be the temporary bonding adhesive or the tape, which may be configured to fix the target device 120 with the adhesive property of the temporary support layer 130 after the target device 120 is placed in the mounting holes 111, thereby reducing the movement of the target device 120 before plastic sealing is performed and improving the structural stability of the packaging bodies.

The target device 120 is placed the mounting holes 111. However, the number and type of the target device 120 inside each of the mounting holes 111 are arranged based on actual needs and are not limited here.

An operation S23 includes: performing plastic sealing on the side of the mounting plate away from the temporary support layer to form a plastic sealing layer filling all the mounting holes, and removing the temporary support layer.

As shown in 3c of FIG. 3, plastic sealing is performed on the side of the mounting plate 110 away from the temporary support layer 130 to form a plastic sealing layer 140 filling all the mounting holes 111.

The plastic sealing layer 140 fills all the mounting hole 111 to wrap and fix the target device 120. The plastic sealing material of the plastic sealing layer 140 may include but is not limited to one or more insulating materials including epoxy resin, polyester resin (PET), polyimide, polyimide, polycarbonate (PC), bismaleimide triazine (BT), and ceramic based materials, etc.

After the plastic sealing is performed, the temporary support layer 130 is removed. Since the target device 120 is in contact with the temporary support layer 130 during mounting, after the temporary support layer 130 is removed, the sides of the target device 120 originally in contact with the temporary support layer 130 is exposed. Therefore, other electrical connections may be performed through the exposed sides of the target device 120.

An operation S24 includes: disposing a processing plate connected to the target device on the side of the mounting plate away from the plastic sealing layer to obtain the packaging bodies.

The structure and manufacturing method of the processing plate may be set based on actual needs.

In some embodiments, the manufacturing method of the processing plate may include: disposing multiple first connectors on the side of the target device away from the plastic sealing layer, filling an insulation layer on the side of the target device away from the plastic sealing layer, and then disposing a second connector on the side of the insulation layer away from the multiple first connectors to obtain the processing plate.

As shown in 3d of FIG. 3, a seed conductive layer 150 is deposited on the side of the target device 120 away from the plastic sealing layer 140. The seed conductive layer 150 serves as a base layer for subsequent electroplating to improve the stability and efficiency of electroplating.

As shown in 3e of FIG. 3, a protective film 160 is attached to the partial side of the seed conductive layer 150 away from the mounting plate 110, and the side of the seed conductive layer 150 away from the mounting plate 110 is electroplated to form an electroplating layer 170.

The method of attaching the protective film 160 to the partial side of the seed conductive layer 150 may include: attaching the protective film 160 to the entire plate, performing exposure and development to retain the partial protective film 160. A part of the target device 120 is exposed from the partial protective film 160, so that the subsequently formed first connectors may be connected to the target device 120 to lead out the signal of the target device 120.

As shown in 3f of FIG. 3, after electroplating is performed, the protective film 160 is removed, and the exposed seed conductive layer 150 is etched to form multiple first connectors 171. The multiple first connectors 171 are formed by the retained seed conductive layer 150 and the retained electroplating layer 170 in contact with the retained seed conductive layer 150.

When the exposed seed conductive layer 150 is etched, a protective film may be covered on the electroplating layer 170 for protection, and the protective film may be removed after the etching is performed.

Some first connectors 171 are connected to the target device 120, thereby leading out the signal of the target device 120.

As shown in 3g of FIG. 3, after the multiple first connectors 171 are manufactured, an insulation layer 180 is filled the side of the target device 120 away from the plastic sealing layer 140.

The thickness of the insulation layer 180 is greater than the thickness of each of the multiple first connectors 171 to fill the gaps between the multiple first connectors 171 and cover the multiple first connectors 171.

As shown in 4a of FIG. 4, a blind-hole 181 is defined on the side of the insulation layer 180 away from the multiple first connectors 171 to expose the some first connectors 171 in contact with the target device 120, and the insulation layer 180 arranged on the other first connectors 171 in contact with the mounting plate 110 are removed.

In some embodiments, the insulation layer 180 may be made of photosensitive materials, such that by photolithography development, the blind-holes 181 may be defined and the insulation layer 180 arranged on the other first connectors 171 in contact with the mounting plate 110 may be removed in this operation. In some embodiments, by laser ablation, the blind-hole 181 may be defined and the insulation layer 180 arranged on the other first connectors 171 in contact with the mounting plate 110 may be removed.

As shown in 4b of FIG. 4, the side of the insulation layer 180 away from the multiple first connectors 171 is electroplated to fill the electroplated material in the blind-hole 181 until the first connectors 171 are connected to the electroplated material, and a conductive layer 190 on the side of the insulation layer 180 away from the multiple first connectors 171 is formed.

The conductive layer 190 is contact with the each of the multiple first connectors 171 through the blind-hole 181, so as to be connected to the target device 120.

As shown in 4c of FIG. 4, the side of the insulation layer 180 away from the multiple first connectors 171 is etched to form a second connector 191, so as to obtain the processing plate 200.

The second connector 191 is contact with each of the multiple first connector 171, so as to be connected to the target device 120.

As shown in 4d of FIG. 4, chemical plating is performed on the exposed side of the second connector 191 to form a chemical plating layer 192. The chemical plating layer 192 may include but is not limited to materials including silver, gold, and/or tin to reduce oxidation of the second connector 191.

The plastic sealing layer 140 is ground on the side of the mounting plate 110 away from the processing plate 200 until the plastic sealing layer 140 is flush with the mounting plate 110 and the mounting plate 110 is exposed, thereby facilitating etching and separation of the plastic sealing layer 140 corresponding to each of the packaging bodies, facilitating the independence of the packaging bodies, and meeting the appearance requirements of each of the packaging bodies.

An operation S25 includes: performing chemical etching on the mounting plate until each of the packaging bodies is separated from each other, and obtaining multiple independent packaging bodies.

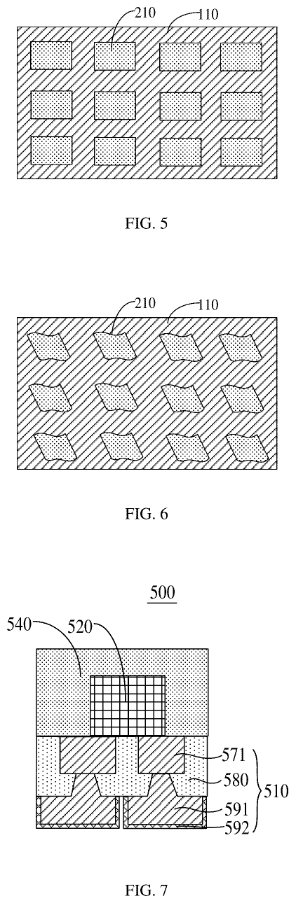

As shown in FIG. 5, FIG. 5 is a structural schematic diagram of an embodiment of a mounting plate on which chemical etching is not performed in the embodiment of FIG. 2.

The mounting plate 110 in this embodiment is arranged with multiple packaging bodies 210 in an array. The appearance of each of the packaging bodies 210 is regular and square.

As shown in FIG. 6, FIG. 6 is a structural schematic diagram of another embodiment of a mounting plate on which chemical etching is not performed in the embodiment of FIG. 2.

The mounting plate 110 in this embodiment is arranged with multiple packaging bodies 210 in an array. The appearance of each of the packaging bodies 210 is irregular and has a high freedom.

As shown in 4e of FIG. 4, the mounting plate 110 on the entire plate is etched by etching solution until each of the packaging bodies 210 is separated from each other, multiple independent packaging bodies 210 are obtained. Since each of the aforementioned mounting holes 111 is a step-hole, each of the packaging bodies 210 with a step appearance may be obtained in this operation.

In some embodiments, the mounting plate 110 is made of glass, and the chemical etching includes chemically etching through hydrofluoric acid etching solution. In some embodiments, the mounting plate 110 is made of metal, and chemical etching includes chemically etching through metal etching solution. The metal etching solution may include acidic etching solution or hydrogen peroxide etching solution.

In other embodiments, the mounting plate 110 may be made of other materials, as long as the etching solution used for chemical etching is capable of etching the corresponding materials of the mounting plate 110.

The method of removing the mounting plate 110 by chemical etching is not limited by mechanical thickness or laser spot diameter, the separation path may be processed into any width, the separation path is not limited to a straight line, and the separation surface is not limited to a plane surface, thereby greatly improving the freedom of batch separation of the packaging bodies and providing more possibilities for the shape of each of the packaging bodies. In this embodiment, etching and separation are simultaneously performed on all separation paths, without queuing in sequence, thereby greatly improving the separation efficiency of the large plate.

In the above operations of this embodiment, the large plate is separated by chemical etching to obtain multiple independent packaging bodies. The separation path is not limited to a straight line, and the separation surface is not limited to a plane surface, which may greatly improve the freedom of batch separation of the packaging bodies and provide more possibilities for the shape of each of the packaging bodies. The chemical etching does not cause phenomena of thermal melting and blackening that affect the quality of the packaging bodies, thereby ensuring the appearance quality of the packaging bodies. In addition, etching and separation are simultaneously performed on all separation paths, without queuing in sequence, thereby greatly improving the separation efficiency of the large plate.

As shown in FIG. 7, FIG. 7 is a structural schematic diagram of a packaging body according to an embodiment of the present disclosure.

A packaging body 500 in this embodiment includes a plastic sealing layer 540 and a target device 520. The target device 520 is received in the plastic sealing layer 540.

The target device 520 may include but is not limited to one or more components including a chip, a resistor, a capacitor, a diode, a transistor, and an inductor, etc. The plastic sealing layer 540 may include but is not limited to one or more insulating materials including epoxy resin, polyester resin (PET), polyimide, polyimide, polycarbonate (PC), bismaleimide triazine (BT), and ceramic based materials, etc.

The packaging body 500 in this embodiment is manufactured by the packaging method in any one of the above embodiments. Therefore, the outer surface of the packaging body 500 in this embodiment is not limited to a plane surface, and has a high freedom in appearance. The packaging body 500 does not occur phenomena of thermal melting and blackening during separation, thereby ensuring the appearance quality of the packaging body 500.

In other embodiments, the packaging body 500 includes a processing plate 510. The processing plate 510 is contact with the target device 520, thereby leading out the signal of the target device 520.

In other embodiments, the processing plate 510 includes an insulation layer 580, and a first connector 571 and a second connector 591 connected one by one.

The first connector 571 is attached to the side of the target device 520 away from the plastic sealing layer 540, and the insulation layer 580 is attached to the side of the target device 520 away from the plastic sealing layer 540 and wraps the first connector 571. The second connector 591 inserts the insulation layer 580 and is connected to the side of the first connector 571 away from the target device 520.

The second connector 591 is exposed from the insulation layer 580 to lead out the signal of the target device 520.

In other embodiments, a chemical plating layer 592 is attached to the exposed surface of the second connector 591, the chemical plating layer 592 includes but is not limited to materials including silver, gold, and/or tin to reduce the oxidation of the second connector 291.

The above description is only some embodiments of the present disclosure and does not limit the scope of the present disclosure. Any equivalent structure or equivalent process transformation made using the description and drawings of the present disclosure, or directly or indirectly applied the description and drawings of the present disclosure in other related technical fields, are included in the present disclosure.

What is claimed is:

1. A packaging method, comprising:
obtaining a mounting plate defining a plurality of mounting holes;
disposing a target device in each of the plurality of mounting holes;
performing plastic sealing on the plurality of mounting holes to form packaging bodies, and each of the packaging bodies wrapping the target device; and
performing chemical etching on the mounting plate until each of the packaging bodies is separated from each other, and obtaining a plurality of independent packaging bodies.

2. The packaging method according to claim 1, wherein the operation of the obtaining the mounting plate comprises:
obtaining an initial plate;
attaching a protective film to an entire side of the initial plate;
exposing and developing the protective film based on an appearance size of each of the packaging bodies to expose an area corresponding to each of the packaging bodies on the initial plate;
performing chemical etching on the initial plate to form the plurality of mounting holes and obtain the mounting plate; wherein the plurality of mounting holes comprise mounting through-holes, mounting blind-holes, mounting threaded-holes, mounting step-holes, or mounting inclined-holes; and
removing the protective film.

3. The packaging method according to claim 1, wherein the mounting plate is made of glass, and the chemical etching comprises chemically etching through hydrofluoric acid etching solution; or the mounting plate is made of metal, and the chemical etching comprises chemically etching through metal etching solution.

4. The packaging method according to claim 1, wherein the operation of the obtaining a mounting plate defining a plurality of mounting holes comprises:
defining the plurality of mounting holes on an initial plate through mechanical punching or laser ablation to obtain the mounting plate.

5. The packaging method according to claim 1, wherein the plurality of mounting holes are through-holes;
the operation of disposing a target device in each of the plurality of mounting holes comprises:
attaching a temporary support layer to one side of the mounting plate; and
placing the target device in each of the plurality of mounting holes from another side of the mounting plate away from the temporary support layer until the target device is in contact with the temporary support layer.

6. The packaging method according to claim 5, wherein the temporary support layer comprises a temporary bonding adhesive, a tape, a glass substrate, a wooden substrate, or a metal substrate.

7. The packaging method according to claim 5, wherein the operation of the performing plastic sealing on the plurality of mounting holes to form packaging bodies, and each of the packaging bodies wrapping target device comprises:
performing plastic sealing on the another side of the mounting plate away from the temporary support layer to form a plastic sealing layer filling the plurality of mounting holes;
removing the temporary support layer; and
disposing a processing plate connected to the target device on one side of the mounting plate away from the plastic sealing layer to obtain the packaging bodies.

8. The packaging method according to claim 7, wherein plastic sealing material of the plastic sealing layer comprises one or more insulating materials comprising epoxy resin, polyester resin, polyimide, polyimide, polycarbonate, bismaleimide triazine, and ceramic based materials.

9. The packaging method according to claim 7, wherein the operation of the disposing a processing plate connected to the target device on one side of the mounting plate away from the plastic sealing layer to obtain the packaging bodies comprises:
disposing a plurality of first connectors on the one side of the target device away from the plastic sealing layer;
filling an insulation layer on the one side of the target device away from the plastic sealing layer;
wherein a thickness of the insulation layer is greater than a thickness of each of the plurality of first connectors, and the insulation layer is spaced apart from the mounting plate; and
disposing a second connector on one side of the insulation layer away from the plurality of first connectors to obtain the processing plate; wherein the second connector is in contact with each of the plurality of first connectors.

10. The packaging method according to claim 9, wherein the operation of the disposing a plurality of first connectors on the one side of the target device away from the plastic sealing layer comprises:
disposing a seed conductive layer on the one side of the target device away from the plastic sealing layer;
attaching a protective film on one partial side of the seed conductive layer away from the mounting plate, and electroplating the one side of the seed conductive layer away from the mounting plate; and
removing the protective film, and etching an exposed part of the seed conductive layer to form the plurality of first connectors.

11. The packaging method according to claim 10, wherein the operation of the attaching a protective film on one partial side of the seed conductive layer away from the mounting plate comprises:
covering the protective film on the entire side of the seed conductive layer away from the mounting plate; and
exposing and developing the protective film to retain the partial protective film; wherein a part of the target device is exposed from the partial protective film.

12. The packaging method according to claim 9, wherein the plurality of first connectors comprises some first connectors in contact with the target device and the other first connectors in contact with the mounting plate, and the operation of the disposing a second connector on one side of the insulation layer away from the plurality of first connectors to obtain the processing plate comprises:
defining a blind-hole on one side of the insulation layer away from the plurality of first connectors to enable each of the plurality of first connectors to be exposed from the blind-hole, and removing the insulation layer in contact with the other first connectors;
electroplating the one side of the insulation layer away from the plurality of first connectors to fill electroplated material in the blind-hole until the plurality of first connectors are connected to electroplated material, and forming a conductive layer on the one side of the insulation layer away from the plurality of first connectors; and
etching the one side of the insulation layer away from the plurality of first connectors to form the second connector and obtain the processing plate.

13. The packaging method according to claim 9, wherein after the operation of the disposing a second connector on one side of the insulation layer away from the plurality of first connectors to obtain the processing plate, the method further comprises:
performing chemical plating on an exposed surface of the second connector; and
grinding the plastic sealing layer on one side of the mounting plate away from the processing plate until the plastic sealing layer is flush with the mounting plate.

14. A packaging method, comprising:
performing chemical etching on an initial plate to obtain a mounting plate with a plurality of mounting holes;
disposing a target device in each of the plurality of mounting holes to form a plurality of packaging bodies; and
performing chemical etching on the mounting plate to separate the packaging bodies;
wherein the chemical etching comprises chemically etching through hydrofluoric acid etching solution or chemically etching through metal etching solution.

15. The packaging method according to claim 14, wherein the operation of the disposing a target device in each of the plurality of mounting holes to form a plurality of packaging bodies comprises:
disposing the target device in each of the plurality of mounting holes; and
performing plastic sealing on each of the plurality of mounting holes to warp the target device, and obtain the plurality of plurality of packaging bodies; wherein each of the plurality of packaging bodies comprises the target device.

16. A packaging body, manufactured by the packaging method according to claim 1, and the packaging body comprising:
a plastic sealing layer; and
a target device, received in the plastic sealing layer.

17. The packaging body according to claim 16, further comprising a processing plate; wherein the processing plate is in contact with the target device to lead out a signal of the target device.

18. The packaging body according to claim 17, wherein
the processing plate comprises an insulation layer, a first connector, and a second connector; the first connector and the second connector are connected one by one;
the first connector is attached to one side of the target device away from the plastic sealing layer, the insulation layer is attached to the one side of the target device away from the plastic sealing layer and wraps the first connector, and the second connector inserts the insulation layer and is connected to one side of the first connector away from the target device; and
the second connector is exposed from the insulation layer to lead out the signal of the target device.

19. The packaging body according to claim 18, wherein
a chemical plating layer is attached to an exposed surface of the second connector, and the chemical plating layer comprises silver, gold, and/or tin.

20. The packaging body according to claim 16, wherein
the target device comprises one or more of a chip, a resistor, a capacitor, a diode, a transistor, and an inductor.
